(19) United States
(12) Patent Application Publication
(10) Pub. No.: US 2026/0302132 A1
(43) Pub. Date: Oct. 1, 2026

(54) DOSE INFORMATION CORRECTION METHOD, DOSE INFORMATION ACQUISITION METHOD FOR EDGE PERIPHERAL REGION OF FIGURE PATTERN, CHARGED PARTICLE BEAM WRITING APPARATUS, AND NON-TRANSITORY COMPUTER-READABLE STORAGE MEDIUM STORING PROGRAM

(71) Applicant: NuFlare Technology, Inc., Yokohama-shi (JP)

(72) Inventors: Yuji FUJIWARA, Yokohama-shi (JP); Shingo MORI, Yokohama-shi (JP); Daisuke HARA, Yokohama-shi (JP); Yuko KAJIWARA, Yokohama-shi (JP)

(73) Assignee: NuFlare Technology, Inc., Yokohama-shi (JP)

(21) Appl. No.: 19/547,898

(22) Filed: Feb. 24, 2026

(30) Foreign Application Priority Data
Mar. 27, 2025 (JP) 2025-054494

(51) Int. Cl. H01J 37/304; H01J 37/317

(52) U.S. Cl. CPC H01J 37/304; H01J 37/3174

(57) ABSTRACT

According to one aspect of the present invention, a dose information correction method includes: setting a reference correction amount for correcting the dose information; calculating, for each mesh region, a gradient of the dose information defined for a mesh region by using the dose information defined for the mesh region and the dose information defined for a peripheral mesh region around the mesh region; calculating, for each mesh region, an individual correction amount of the dose information of the mesh region to be applied along a direction of the gradient by using a value of a calculated gradient and the reference correction amount; and generating and outputting a corrected dose information map in which corrected dose information obtained by correcting the dose information of the mesh region using a calculated individual correction amount is defined for each mesh region.

### CROSS-REFERENCE TO RELATED APPLICATION

This application is based upon and claims the benefit of priority from prior Japanese Patent Application No. 2025-054494 filed on Mar. 27, 2025 in Japan, the entire contents of which are incorporated herein by reference.

### BACKGROUND OF THE INVENTION

### Field of the Invention

One aspect of the present invention relates to a dose information correction method, a dose information acquisition method for an edge peripheral region of a figure pattern, a charged particle beam writing apparatus, and a non-transitory computer-readable storage medium storing program, and relates to, for example, a method for correcting rasterized dose information.

### Related Art

Lithography technology contributing to the progress of miniaturization of semiconductor devices, is a very important and only process to generate a pattern among semiconductor manufacturing processes. Recently, with the high integration of LSI, a circuit line width required for the semiconductor devices becomes finer year by year. Here, the electron beam writing (or “drawing”) technology inherently has excellent resolution, and writing is performed on a wafer or the like using an electron beam.

For example, there is a writing apparatus using multiple beams. As compared with a case of performing writing with one electron beam, irradiation of more beams can be performed at one time by using the multiple beams, so that the throughput can be greatly improved. In such a multiple beam writing apparatus, for example, electron beams emitted from an electron emission source assembly are passed through a mask having a plurality of holes to form multiple beams, each beam blanking-controlled and not shielded is reduced by an optical system, each beam is deflected by a deflector, and a desired position on a target object is irradiated with each beam.

Here, in lithography such as exposure transfer, the pattern is often not transferred as an input figure. For example, the line width becomes thick or thin due to a process, a pattern density, or the like. As a method for solving such a problem, there is bias correction. In electron beam writing including multiple beam writing, a writing pattern size is adjusted so as to have a desired size after transfer by giving an excessive or insufficient amount of line width to data in advance. Figure-based bias correction and pixel-based bias correction have been studied for bias correction. In the figure-based bias correction, a line segment or a vertex is corrected at a stage of figure data (vector data). However, there is a disadvantage that a load of calculation processing depends on an input figure and a figure density. In the pixel-based bias correction, after vector data is rasterized into pixel data, the dose is corrected on a bitmap defined by multiple values. However, there are disadvantages such as relatively heavy processing and high implementation cost.

Here, as the conventional pixel-based bias correction, the following method is disclosed (see, for example, U.S. Pat. No. 10,444,629). After rasterizing data into pixel data, a pattern edge (contour) is detected from the pixel data to specify an edge position (vector data). Then, the edge position (vector data) is moved by a desired size and then a value of each pixel is calculated from the edge position (vector data). However, in such a method, the edge position should be calculated after rasterization, which is essentially the same as performing the figure-based bias correction. In addition, in a case where edges of adjacent patterns overlap each other on data by bias correction, logical operation processing of the overlapping region becomes complicated. For this reason, a method capable of performing correction without considering the position of the pattern edge is required.

### BRIEF SUMMARY OF THE INVENTION

According to one aspect of the present invention, a dose information correction method includes:
acquiring a dose information map in which dose information related to a dose of a charged particle beam for writing a figure pattern on a target object with the charged particle beam is defined for each mesh region of a plurality of mesh regions obtained by dividing a writing region of the target object;
setting a reference correction amount for correcting the dose information;
calculating, for each mesh region, a gradient of the dose information defined for a mesh region by using the dose information defined for the mesh region and the dose information defined for a peripheral mesh region around the mesh region;
calculating, for each mesh region, an individual correction amount of the dose information of the mesh region to be applied along a direction of the gradient by using a value of a calculated gradient and the reference correction amount; and
generating and outputting a corrected dose information map in which corrected dose information obtained by correcting the dose information of the mesh region using a calculated individual correction amount is defined for each mesh region.

According to another aspect of the present invention, a dose information acquisition method for an edge peripheral region of a figure pattern, the dose information acquisition method includes:
acquiring a dose information map in which dose information related to a dose of a charged particle beam for writing a figure pattern on a target object with the charged particle beam is defined for each mesh region of a plurality of mesh regions obtained by dividing a writing region of the target object;
setting a reference correction amount for correcting the dose information;
calculating, for each mesh region, a gradient of the dose information defined for a mesh region by using the dose information defined for the mesh region and the dose information defined for a peripheral mesh region around the mesh region;
calculating, for each mesh region, an individual correction amount of the dose information of the mesh region to be applied along a direction of the gradient by using a value of a calculated gradient and the reference correction amount;
generating a corrected dose information map in which corrected dose information obtained by correcting the dose information of the mesh region using a calculated individual correction amount is defined for each mesh region; and
generating and outputting an edge peripheral region dose information map in which dose information of an edge peripheral region of a figure pattern is defined for each mesh region by calculating a difference between the dose information map and the corrected dose information map.

According to yet another aspect of the present invention, a dose information correction method includes:
generating a dose information map in which dose information related to a dose of a charged particle beam for writing a figure pattern on a target object with the charged particle beam is defined for each mesh region of a plurality of mesh regions obtained by dividing a writing region of the target object;
acquiring an edge peripheral region dose information map by the method according to claim 6; and
generating and outputting an edge peripheral corrected dose information map in which dose information of the edge peripheral region of the figure pattern is corrected by adding an acquired edge peripheral region dose information map to the dose information map.

According to yet another aspect of the present invention, a charged particle beam writing apparatus includes:
a dose information map acquisition circuit configured to acquire a dose information map in which dose information related to a dose of the charged particle beam for writing a figure pattern on a target object with the charged particle beam is defined for each mesh region of a plurality of mesh regions obtained by dividing a writing region of the target object;
a setting circuit configured to set a reference correction amount for correcting the dose information;
a gradient calculation circuit configured to calculate, for each mesh region, a gradient of the dose information defined for a mesh region by using the dose information defined for the mesh region and the dose information defined for a peripheral mesh region around the mesh region;
an individual correction amount calculation circuit configured to calculate, for each mesh region, an individual correction amount of the dose information of the mesh region to be applied along a direction of the gradient using a value of a calculated gradient and the reference correction amount;
a corrected dose information map generation circuit configured to generate a corrected dose information map in which corrected dose information obtained by correcting the dose information of the mesh region using a calculated individual correction amount is defined for each mesh region; and
a writing mechanism configured to write a pattern on the target object with a charged particle beam of a dose based on the corrected dose information defined in a generated corrected dose information map.

According to yet another aspect of the present invention, a charged particle beam writing apparatus includes:
a dose information map acquisition circuit configured to acquire a dose information map in which dose information related to a dose of the charged particle beam for writing a figure pattern on a target object with the charged particle beam is defined for each mesh region of a plurality of mesh regions obtained by dividing a writing region of the target object;
a setting circuit configured to set a reference correction amount for correcting the dose information;
a gradient calculation circuit configured to calculate, for each mesh region, a gradient of the dose information defined for a mesh region by using the dose information defined for the mesh region and the dose information defined for a peripheral mesh region around the mesh region;
an individual correction amount calculation circuit configured to calculate, for each mesh region, an individual correction amount of the dose information of the mesh region to be applied along a direction of the gradient using a value of a calculated gradient and the reference correction amount;
a corrected dose information map generation circuit configured to generate a corrected dose information map in which corrected dose information obtained by correcting the dose information of the mesh region using a calculated individual correction amount is defined for each mesh region;
an edge peripheral region dose information map generating circuit configured to generate an edge peripheral region dose information map in which dose information of an edge peripheral region of a figure pattern is defined for each mesh region by calculating a difference between the dose information map and the corrected dose information map; and
a writing mechanism configured to write a pattern on the target object with a charged particle beam of a dose based on dose information corrected using the edge peripheral region dose information map.

According to yet another aspect of the present invention, a non-transitory computer-readable storage medium storing a program for causing a computer to execute processing includes:
acquiring a dose information map in which dose information related to a dose of a charged particle beam for writing a figure pattern on a target object with the charged particle beam is defined for each mesh region of a plurality of mesh regions obtained by dividing a writing region of the target object;
setting a reference correction amount for correcting the dose information;
calculating, for each mesh region, a gradient of the dose information defined for a mesh region by using the dose information defined for the mesh region and the dose information defined for a peripheral mesh region around the mesh region;
storing a calculated gradient of the dose information in a storage device;
reading the gradient of the dose information from the storage device and calculating, for each mesh region, an individual correction amount of the dose information of the mesh region to be applied along a direction of the gradient using a value of a calculated gradient and the reference correction amount; and
generating and outputting a corrected dose information map in which corrected dose information obtained by correcting the dose information of the mesh region using a calculated individual correction amount is defined for each mesh region.

### BRIEF DESCRIPTION OF THE DRAWINGS

FIG. 1 is a conceptual diagram illustrating an example of a configuration of a writing apparatus in a first embodiment;

FIG. 2 is a conceptual diagram illustrating an example of a configuration of a shaping aperture array substrate in the first embodiment;

FIG. 3 is a cross-sectional view illustrating an example of a configuration of a blanking aperture array mechanism in the first embodiment;

FIG. 4 is a conceptual diagram illustrating an example of a writing operation in the first embodiment;

FIG. 5 is a diagram illustrating an example of a multiple beam irradiation region and a writing target pixel in the first embodiment;

FIG. 6 is a diagram illustrating an example of a multiple beam writing operation in the first embodiment;

FIG. 7 is a flowchart illustrating an example of a bias correction method in a comparative example of the first embodiment;

FIG. 8 is a flowchart illustrating an example of main steps of a writing method in the first embodiment;

FIG. 9 is a diagram illustrating an example of a transformed advection model in the first embodiment;

FIG. 10 is a diagram illustrating a part of an example of a dose information map in the first embodiment;

FIG. 11 is a diagram illustrating a part of an example of a corrected dose information map after first bias calculation processing in the first embodiment;

FIG. 12 is a diagram illustrating an example of a reference bias amount map in the first embodiment;

FIG. 13 is a diagram illustrating a part of an example of an original dose information map before bias calculation processing in the first embodiment;

FIG. 14 is a diagram illustrating a part of an example of a corrected dose information map after first bias calculation processing in the first embodiment;

FIG. 15 is a diagram illustrating a part of an example of a corrected dose information map after second bias calculation processing in the first embodiment;

FIG. 16 is a diagram illustrating an example of a map image corresponding to a dose information map after bias correction in the first embodiment;

FIG. 17 is a diagram illustrating an example of a map image and a dose corresponding to a dose information map before bias correction in the first embodiment;

FIG. 18 is a diagram illustrating an example of a map image and a dose corresponding to a corrected dose information map after bias correction in the first embodiment;

FIG. 19 is a diagram illustrating an example of a map image and a dose corresponding to a dose information map of two adjacent circle patterns before bias correction in the first embodiment;

FIG. 20 is a diagram illustrating an example of a map image and a dose corresponding to a dose information map of two adjacent circle patterns after bias correction in the first embodiment;

FIG. 21 is a conceptual diagram illustrating an example of a configuration of a writing apparatus in a second embodiment;

FIG. 22 is a flowchart illustrating an example of main steps of a writing method in the second embodiment;

FIG. 23 is a diagram illustrating an example of an image from generation of a dose information map to generation of a corrected dose map using an edge peripheral region dose information map in the second embodiment;

FIG. 24 is a diagram illustrating an example of a pattern in which an edge is emphasized in the second embodiment;

FIG. 25 is a diagram illustrating another example of a pattern in which an edge is emphasized in the second embodiment;

FIG. 26 is a flowchart illustrating an example of main steps of a writing method in a first modification of the second embodiment; and

FIG. 27 is a flowchart illustrating an example of main steps of a writing method in a second modification of the second embodiment.

### DETAILED DESCRIPTION OF THE INVENTION

Hereinafter, embodiments provide a method and an apparatus capable of performing bias correction on pixel data of information such as a dose of a charged particle beam without considering a position of a pattern edge.

In the following embodiments, a configuration using an electron beam as an example of a charged particle beam will be described. However, the charged particle beam is not limited to the electron beam and may be a beam using a charged particle such as an ion beam. Hereinafter, a configuration using multiple beams as the electron beam will be described, but the present invention is not limited thereto. A configuration using a single beam may be used.

### First Embodiment

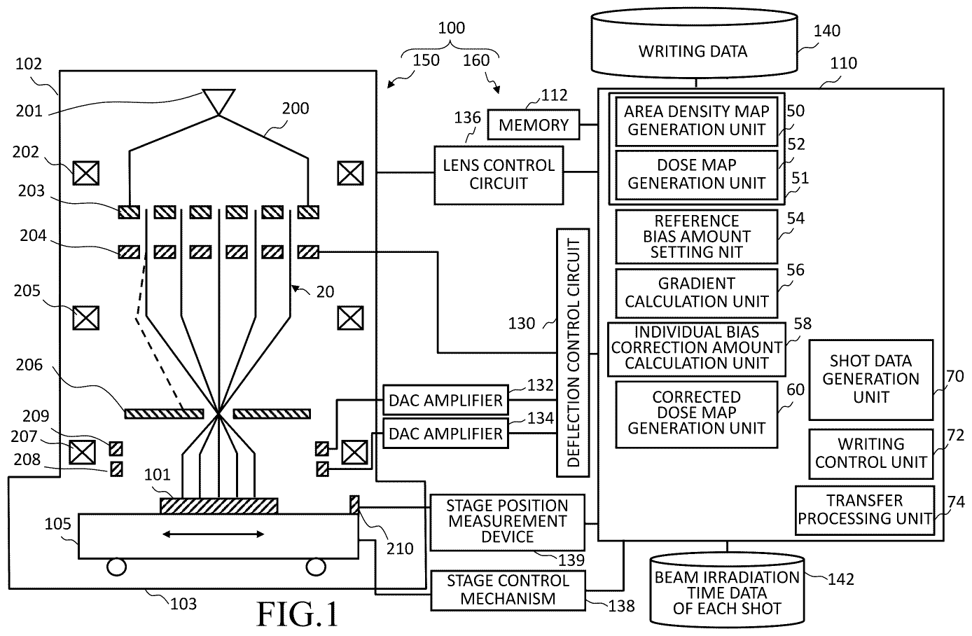

FIG. 1 is a conceptual diagram illustrating an example of a configuration of a writing apparatus in a first embodiment. In FIG. 1, a writing apparatus 100 includes a writing mechanism 150 and a control system circuit 160. The writing apparatus 100 is an example of a multiple charged particle beam writing apparatus and an example of a multiple charged particle beam exposure apparatus. The writing mechanism 150 includes an electron optical column 102 (electron beam column) and a writing chamber 103. An electron emission source 201, an illumination lens 202, a shaping aperture array substrate 203, a blanking aperture array mechanism 204, a reduction lens 205, a limiting aperture substrate 206, an objective lens 207, a main deflector 208, and a sub-deflector 209 are disposed in the electron optical column 102.

An XY stage 105 is disposed in the writing chamber 103. On the XY stage 105, a target object 101 such as a mask to be a substrate to be written at the time of writing (at the time of exposure) is disposed. The target object 101 includes an exposure mask and the like for manufacturing a semiconductor device. In addition, the target object 101 includes mask blanks on which a resist is applied and on which nothing is written. Further, a mirror 210 for measuring a position of the XY stage 105 is disposed on the XY stage 105.

The control system circuit 160 has a control computer 110, a memory 112, a deflection control circuit 130, digital/analog conversion (DAC) amplifier units 132 and 134, a lens control circuit 136, a stage control mechanism 138, a stage position measurement device 139, and storage devices 140 and 142 such as magnetic disk drives. The control computer 110, the memory 112, the deflection control circuit 130, the lens control circuit 136, the stage control mechanism 138, the stage position measurement device 139, and the storage devices 140 and 142 are connected to each other via a bus (not illustrated). The DAC amplifier units 132 and 134 and the blanking aperture array mechanism 204 are connected to the deflection control circuit 130. The sub-deflector 209 is configured by four or more electrodes and is controlled by the deflection control circuit 130 via the DAC amplifier 132 for each electrode. The main deflector 208 is configured by four or more electrodes and is controlled by the deflection control circuit 130 via the DAC amplifier 134 for each electrode. A lens group such as the illumination lens 202, the reduction lens 205, and the objective lens 207 is controlled by the lens control circuit 136. As the lens group, an electromagnetic lens or an electrostatic lens is used.

The position of the XY stage 105 is controlled by driving of a motor of each shaft (not illustrated) controlled by the stage control mechanism 138. The stage position measurement device 139 receives reflected light from the mirror 210 and measures a position of the XY stage 105 by the principle of a laser interference method.

In the control computer 110, a rasterization processing unit 51, a reference bias amount setting unit 54, a gradient calculation unit 56, an individual bias correction amount calculation unit 58, a corrected dose map generation unit 60, a shot data generation unit 70, a writing control unit 72, and a transfer processing unit 74 are arranged. In the rasterization processing unit 51, an area density map generation unit 50 and a dose map generation unit 52 are arranged.

Each “unit” such as the rasterization processing unit 51 (the area density map generation unit 50 and the dose map generation unit 52), the reference bias amount setting unit 54, the gradient calculation unit 56, the individual bias correction amount calculation unit 58, the corrected dose map generation unit 60, the shot data generation unit 70, the writing control unit 72, and the transfer processing unit 74 includes a processing circuit. The processing circuit includes an electric circuit, a computer, a processor, a circuit board, a quantum circuit, or a semiconductor device, for example. Each “unit” may use a common processing circuit (the same processing circuit) or may use a different processing circuit (a separate processing circuit). Information input to and output from the rasterization processing unit 51 (the area density map generation unit 50 and the dose map generation unit 52), the reference bias amount setting unit 54, the gradient calculation unit 56, the individual bias correction amount calculation unit 58, the corrected dose map generation unit 60, the shot data generation unit 70, the writing control unit 72, and the transfer processing unit 74 and information during calculation are stored in the memory 112 each time.

The writing operation of the writing apparatus 100 is controlled by the writing control unit 72. In other words, the writing control unit 72 (an example of a control circuit) controls the writing mechanism 150. In addition, the transfer processing of beam irradiation time data of each shot to the deflection control circuit 130 is controlled by the transfer processing unit 74.

Further, writing data (chip data) is input from the outside of the writing apparatus 100 and stored in the storage device 140. In the chip data, information of a plurality of figure patterns forming a chip pattern is defined. Specifically, for each figure pattern, for example, the coordinates of each vertex are defined in the order of forming a figure. Alternatively, for example, a figure code, coordinates, a size, and the like are defined for each figure pattern.

Here, in FIG. 1, the configuration necessary for describing the first embodiment is described. The writing apparatus 100 may generally include other necessary configuration.

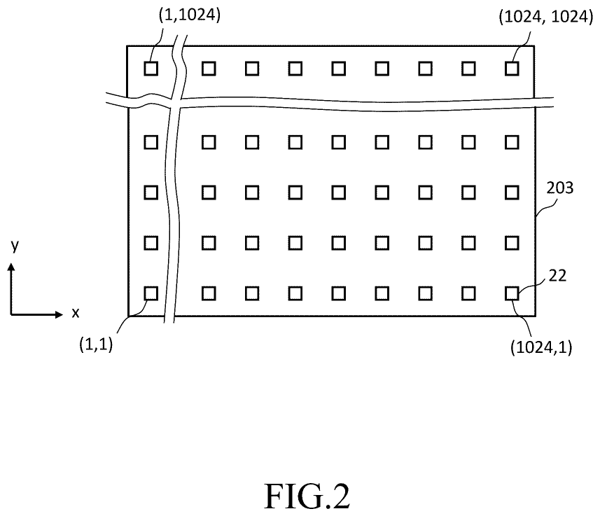

FIG. 2 is a conceptual diagram illustrating an example of a configuration of a shaping aperture array substrate in the first embodiment. In FIG. 2, in the shaping aperture array substrate 203, p×q (p, q≥2) holes (openings) 22 in a length direction (y direction) and a width direction (x direction) are formed in a matrix of rows and columns at a predetermined arrangement pitch. In the example of FIG. 2, a case where 1024×1024 holes 22 are formed in the width and length directions (x and y directions) is illustrated. The number of the holes 22 is not limited thereto. For example, 512×512 or 32×32 holes 22 may be formed. Each hole 22 is formed of a rectangle having the same dimension and shape. Alternatively, each hole 22 may have a shape of a circle with the same diameter. A part of electron beams 200 passes through the plurality of holes 22, so that multiple beams 20 are formed. In other words, the shaping aperture array substrate 203 forms the multiple beams 20.

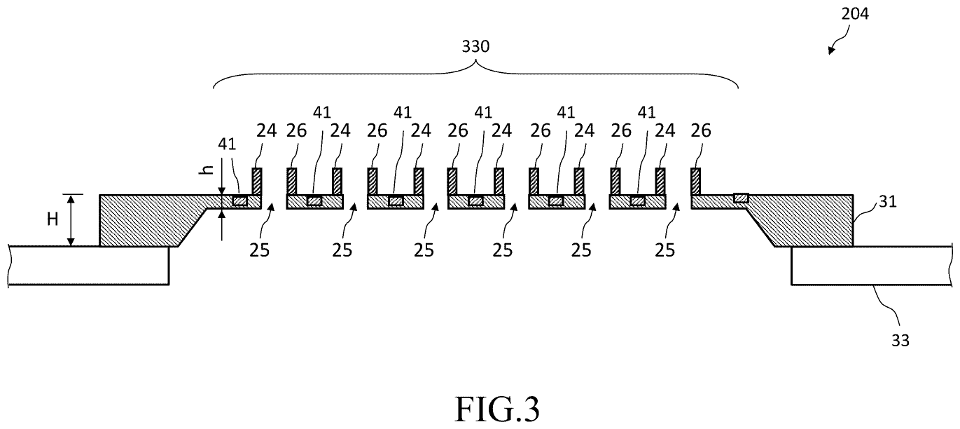

FIG. 3 is a cross-sectional view illustrating an example of a configuration of a blanking aperture array mechanism in the first embodiment. As illustrated in FIG. 3, in the blanking aperture array mechanism 204, the blanking aperture array substrate 31 using a semiconductor substrate made of silicon or the like is arranged on a support base 33. In a membrane region 330 in a center portion of the blanking aperture array substrate 31, a passing hole 25 (opening) for passing each beam of the multiple beams 20 is formed at a position corresponding to each hole 22 of the shaping aperture array substrate 203 illustrated in FIG. 2. A pair (blanker: blanking deflector) of a control electrode 24 and a counter electrode 26 is disposed at positions facing each other across the passing hole 25. In addition, a control circuit 41 (logic circuit) that applies a deflection voltage to the control electrode 24 for each of the passing holes 25 is disposed inside the blanking aperture array substrate 31 in the vicinity of each of the passing holes 25. The counter electrode 26 for each beam is connected to a ground.

An amplifier (an example of a switching circuit) not illustrated in the drawings is disposed in the control circuit 41. As an example of the amplifier, a complementary MOS (CMOS) inverter circuit serving as a switching circuit is disposed. Any one of a low (L) potential (for example, the ground potential) lower than a threshold voltage and a high (H) potential (for example, 1.5 V) equal to or higher than the threshold voltage is applied as a control signal to an input (IN) of the CMOS inverter circuit. In the first embodiment, in a state where the L potential is applied to the input (IN) of the CMOS inverter circuit, control is performed such that the output (OUT) of the CMOS inverter circuit applied to the control circuit 41 becomes the positive potential (Vdd), and the corresponding beam is deflected by the electric field due to the potential difference from the ground potential of the counter electrode 26 and shielded by the limiting aperture substrate 206 to turn off the beam. On the other hand, in a state (active state) where the H potential is applied to the input (IN) of the CMOS inverter circuit, control is performed such that the output (OUT) of the CMOS inverter circuit becomes a ground potential, the potential difference from the ground potential of the counter electrode 26 disappears, and the corresponding beam is not deflected and passes through the limiting aperture substrate 206 to turn on the beam. By such deflection, blanking control is performed.

Next, a specific example of the operation of the writing mechanism 150 will be described. The electron beams 200 emitted from the electron emission source 201 (emission source) illuminate the entire shaping aperture array substrate 203 substantially vertically by the illumination lens 202. The plurality of rectangular holes 22 (openings) are formed in the shaping aperture array substrate 203, and the electron beams 200 illuminate a region including all the plurality of holes 22. Each part of the electron beams 200 with which the positions of the plurality of holes 22 are irradiated passes through the plurality of holes 22 of the shaping aperture array substrate 203, so that multiple beams (a plurality of electron beams) 20 having, for example, a rectangular shape are formed. The multiple beams 20 pass through the respective corresponding blankers of the blanking aperture array mechanism 204. Such blankers perform blanking control on the beams individually passing through the blankers so that the beams are turned on for a set writing time (beam irradiation time).

The multiple beams 20 that have passed through the blanking aperture array mechanism 204 are reduced by the reduction lens 205 and travel toward the center hole formed in the limiting aperture substrate 206. Here, the electron beam deflected by the blanker of the blanking aperture array mechanism 204 is shifted in position from the center hole of the limiting aperture substrate 206 and is shielded by the limiting aperture substrate 206. On the other hand, electron beams not deflected by the blanker of the blanking aperture array mechanism 204 pass through the center hole of the limiting aperture substrate 206 as illustrated in FIG. 1. As described above, the limiting aperture substrate 206 shields each beam deflected to be in the beam OFF state by the blanker of the blanking aperture array mechanism 204. In addition, each beam of one shot is formed by the beam having passed through the limiting aperture substrate 206, formed from beam ON to beam OFF. The multiple beams 20 having passed through the limiting aperture substrate 206 are focused by the objective lens 207 to become a pattern image of a desired reduction ratio, the entire multiple beams 20 having passed through the limiting aperture substrate 206 are collectively deflected in the same direction by the main deflector 208 and the sub-deflector 209, and the respective irradiation positions of the beams on the target object 101 are irradiated with the multiple beams. In addition, for example, when the XY stage 105 is continuously moved, tracking control is performed by the main deflector 208 so that the irradiation position of the beam follows the movement of the XY stage 105. The multiple beams 20 to be irradiated at one time are ideally arranged at a pitch obtained by multiplying the arrangement pitch of the plurality of holes 22 of the shaping aperture array substrate 203 by the desired reduction ratio.

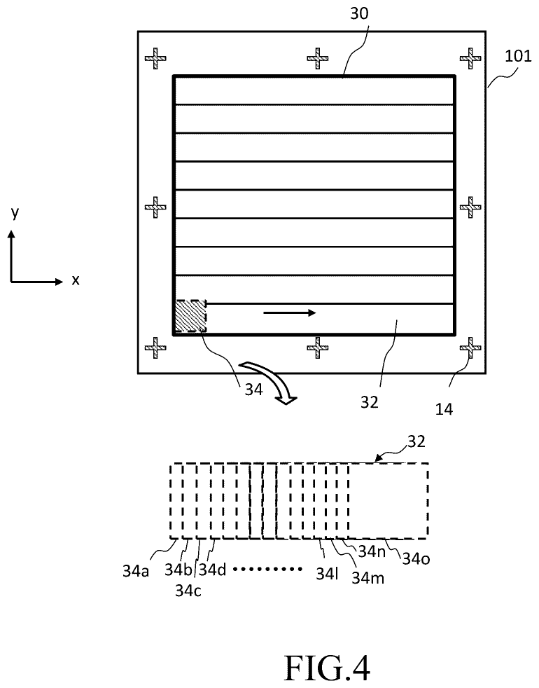

FIG. 4 is a conceptual diagram illustrating an example of a writing operation in the first embodiment. As illustrated in FIG. 4, a writing region 30 (chip region) (thick frame) of the target object 101 is virtually divided into a plurality of stripe regions 32 having a predetermined width and a strip shape in the y direction, for example. In the example of FIG. 4, the case where the writing region 30 of the target object 101 is divided into the plurality of stripe regions 32 with substantially the same width size as the size of an irradiation region 34 (writing field) in design which can be irradiated with one irradiation of the multiple beams 20 in the y direction is illustrated.

In addition, a plurality of alignment marks 14 are arranged around the writing region 30 (chip region). For example, a cross pattern is preferably used as the alignment mark 14. In the example of FIG. 4, a case where one cross pattern is arranged as each alignment mark 14 is illustrated, but the present invention is not limited thereto. For example, each alignment mark 14 may suitably include a set of a large cross pattern and a small cross pattern having the same line width. The large cross pattern is configured by a pattern in which the length of each line pattern forming the cross is long, and the small cross pattern is configured by a pattern in which the length of each line pattern forming the cross is short.

In addition, in the example of FIG. 4, a case where writing of multiplicity of 1 is performed is illustrated. Multiple writing (N-pass writing) in which writing is repeatedly performed by moving each of the stripe regions 32 in the x direction of the XY stage a plurality of times (N times) may be performed. In this case, it is preferable to shift the stripe region 32 for each pass. For example, in the N-pass writing, it is preferable to shift the position by a 1/N size of the width of the stripe region 32. The multiplicity is not limited to 2, and may be 3 or more.

Further, the above-described position shift is not limited to the y direction, and may be applied to the x direction. Next, an example of the writing operation will be described.

First, the XY stage 105 is moved and adjusted so that the irradiation region 34 of the multiple beams 20 is located at the left end of the first stripe region 32 of the first stripe layer or at a position on the further left side. At the time of writing of the first stripe region 32, the writing is advanced relatively in the x direction by moving the XY stage 105 in the −x direction, for example. The XY stage 105 is continuously moved at a constant speed, for example.

After the writing of the first stripe region 32 is completed, the stage position is moved in the −y direction by the width size of the stripe region 32.

Next, adjustment is performed such that the irradiation region 34 of the multiple beams 20 is located at the left end of the second stripe region 32 or at a position on the further left side. Then, by moving the XY stage 105 in, for example, the −x direction, writing is advanced relatively in the x direction. As a result, writing of the second stripe region 32 is performed. Thereafter, writing of each stripe region 32 is performed by similarly repeating the above.

In the example of FIG. 4, the case where writing of each stripe region 32 is advanced in the same direction has been illustrated, but the present invention is not limited thereto. For example, for the stripe region 32 to be written next to the stripe region 32 in which writing has been advanced in the x direction, writing may be performed in the −x direction by moving the XY stage 105 in, for example, the x direction. By performing writing while alternately changing the direction in this manner, the stage moving time can be shortened, and the writing time can be shortened accordingly. In one shot, the multiple beams 20 formed by passing through the respective holes 22 of the shaping aperture array substrate 203 form a plurality of shot patterns as many as the respective holes 22 at the maximum at one time.

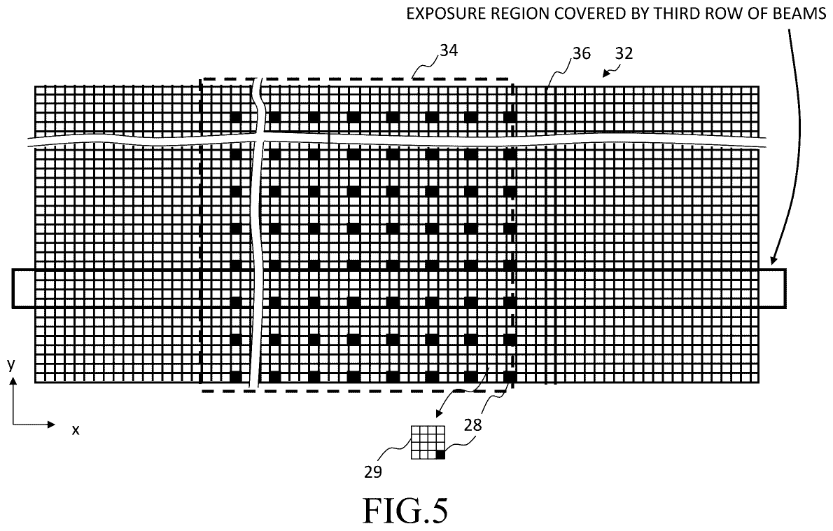

FIG. 5 is a diagram illustrating an example of a multiple beam irradiation region and a writing target pixel in the first embodiment. In FIG. 5, the stripe region 32 is divided into a plurality of mesh regions of a mesh shape by the beam size of the multiple beams 20, for example. Each of such mesh regions is a writing target pixel 36 (beam irradiation unit region and irradiation position). The size of the writing target pixel 36 is not limited to the beam size, and may be any size regardless of the beam size. For example, the size of the pixel may be 1/n (n is an integer of 1 or more) of the beam size. In the example of FIG. 5, the case where the writing region of the target object 101 is divided into the plurality of stripe regions 32 with substantially the same width size as the size of the irradiation region 34 (writing field) which can be irradiated with one irradiation of the multiple beams 20 in the y direction is illustrated. The size of the rectangular irradiation region 34 in the x direction can be defined by the number of beams in the x direction×inter-beam pitch in the x direction. The size of the rectangular irradiation region 34 in the y direction can be defined by the number of beams in the y direction×inter-beam pitch in the y direction. In the example of FIG. 5, for example, 1024×1024 multiple beams are illustrated to be abbreviated to 8×8 multiple beams. Further, in the irradiation region 34, a plurality of pixels 28 (beam writing positions) which can be irradiated with one shot of the multiple beams 20 are illustrated. The pitch between the adjacent pixels 28 is the inter-beam pitch of the multiple beams. One sub-irradiation region 29 (pitch cell region) is configured by a rectangular region surrounded by the size of the inter-beam pitch in the x and y directions. In the example of FIG. 5, the case where each sub-irradiation region 29 is configured by 4×4 pixels is illustrated.

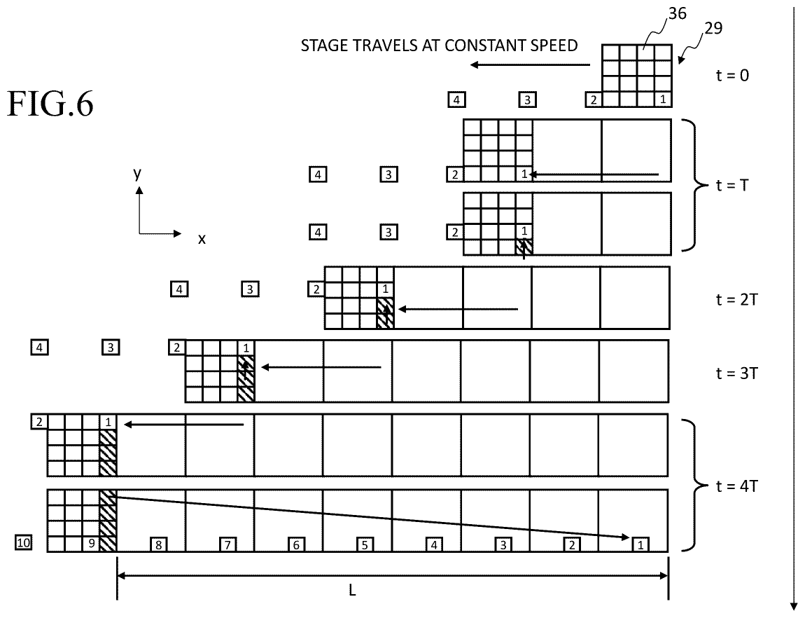

FIG. 6 is a diagram illustrating an example of a multiple beam writing operation in the first embodiment. In the example of FIG. 6, a case where the inside of each sub-irradiation region 29 is written with four different beams is illustrated. In addition, the example of FIG. 6 illustrates a writing operation in which the XY stage 105 continuously moves at a speed of moving by the distance L corresponding to the 8 beam pitches while a ¼ (1/the number of beams used for irradiation) region in each sub-irradiation region 29 is written. In the writing operation illustrated in the example of FIG. 6, for example, four different pixels in the same sub-irradiation region 29 are written (exposed) by four shots of the multiple beams 20 in the shot cycle T while sequentially shifting the irradiation positions (pixels 36) by the sub-deflector 209 while the XY stage 105 moves by the distance L corresponding to the 8 beam pitches. During writing (exposing) of the four pixels, the irradiation region 34 is caused to follow the movement of the XY stage 105 by deflecting the entire multiple beams 20 collectively by the main deflector 208, such that a relative position with the target object 101 is not shifted due to the movement of the XY stage 105. In other words, tracking control is performed. When one tracking cycle ends, tracking is reset, and the tracking position returns to the tracking start position. Since the writing of the first pixel column from the right side of each sub-irradiation region 29 is completed, the sub-deflector 209 first performs deflection so as to adjust (shift) the beam writing position so as to write the second pixel column from the right, for example, which has not yet been written, of each sub-irradiation region 29 in a next tracking cycle after the tracking is reset. By repeating such an operation during writing of the stripe region 32, the positions of the irradiation regions 34 of the multiple beams 20 sequentially move as illustrated in irradiation regions 34a, 34b, 34c, . . . , and 34o illustrated in the lower diagram of FIG. 4, and writing is performed.

Here, as described above, in lithography such as exposure transfer, the pattern is often not transferred as the input figure. For example, the line width becomes thick or thin due to a process, a pattern density, or the like. As a method for solving such a problem, there is a method of correcting bias at the stage of electron beam writing.

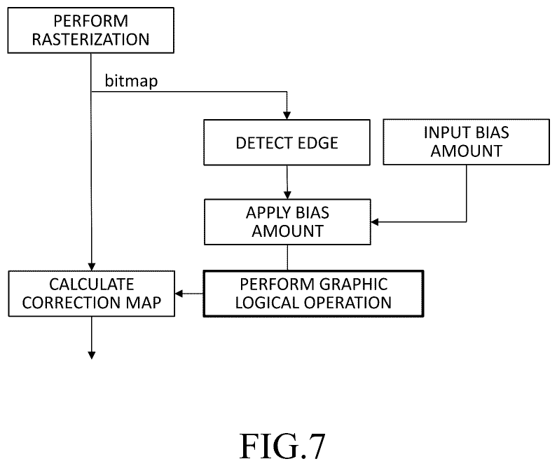

FIG. 7 is a flowchart illustrating an example of a bias correction method in a comparative example of the first embodiment. As illustrated in FIG. 7, figure data (vector data) is rasterized into pixel data (bitmap). For example, data is converted into dose data. Then, after rasterizing the figure data into the pixel data, a pattern edge (contour) is detected from the pixel data, and an edge position (vector data) is specified. Then, a bias amount is input to move the edge position (vector data) by a desired size. At this time, in a case where edges of adjacent patterns overlap each other on data by the bias correction, graphic logical operation processing of the overlapping region is performed. Thereafter, a corrected dose map is created by calculating a value of each pixel from the edge position (vector data). However, in such a method, the edge position should be calculated after rasterization, which is essentially the same as performing the figure-based bias correction. In addition, in a case where edges of adjacent patterns overlap each other on data by bias correction, logical operation processing of the overlapping region becomes complicated. For this reason, a method capable of performing correction without considering the position of the pattern edge is required. Therefore, in the first embodiment, the bias correction is performed on the pixel data without considering the position of the pattern edge by applying an advection equation for transporting the physical quantity in the gradient direction. The details will be described below.

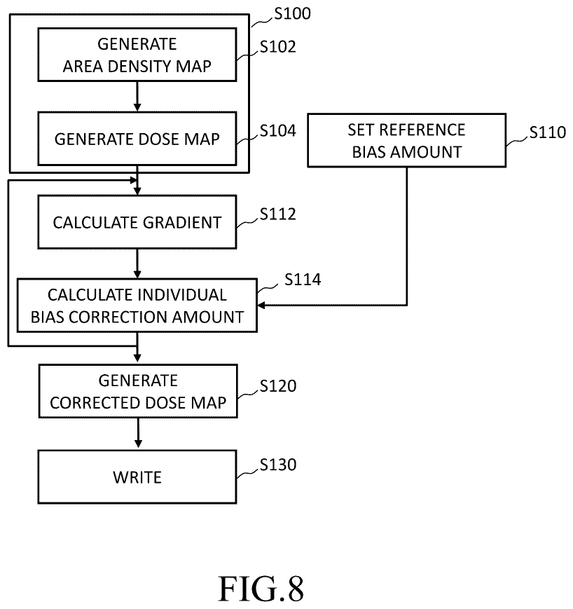

FIG. 8 is a flowchart illustrating an example of main steps of a writing method in the first embodiment. In FIG. 8, the writing method in the first embodiment performs a series of steps including a rasterization processing step (S100), a reference bias amount setting step (S110), a gradient calculation step (S112), an individual bias correction amount calculation step (S114), a corrected dose map generation step (S120), and a writing step (S130). In the rasterization processing step (S100), an area density map generation step (S102) and a dose map generation step (S104) are performed as internal steps.

As the rasterization processing step (S100), the rasterization processing unit 51 (an example of a dose information map acquisition unit) acquires a dose information map in which dose information related to the dose of each beam of the multiple beams 20 for writing a figure pattern on the target object 101 with the multiple beams 20 is defined for each pixel 36 of the plurality of pixels 36 (mesh regions) obtained by dividing the stripe region 32 (an example of a writing region) of the target object 101. The dose information may be an area density or a dose. Data after dose calculation may be used. The dose information map may be generated in the writing apparatus 100, or the dose information map may be input from the outside and stored in a storage device or the like. For example, in a case where the dose information map is generated in the writing apparatus 100, specifically, the following operation is performed.

As the area density map generation step (S102), the area density map generation unit 50 (another example of the dose information map acquisition unit) reads chip pattern data (writing data) from the storage device 140 and performs rasterization processing. Specifically, the pattern area density ρ (an example of the dose information) is calculated for each pixel 36, and the area density map (an example of the dose information map) in which the pattern area density is defined for each pixel 36 is generated.

Next, as the dose map generation step (S104), the dose map generation unit 52 calculates the dose D for irradiating the pixel 36 for each pixel 36. The dose D may be calculated as a value obtained by multiplying preset base doses of the beam Dbase by a proximity effect-corrected dose Dp and a pattern area density ρ, for example. The proximity effect-corrected dose Dp is defined as a relative value normalized with the base doses of the beam Dbase as 1. For the proximity effect-corrected dose Dp, the writing region (here, for example, the stripe region 32) is virtually divided into a plurality of proximity mesh regions (proximity effect correction calculation mesh regions) in a mesh shape with a predetermined size. The size of the proximity mesh region is preferably set to about 1/10 of a range of influence of a proximity effect, for example, about 1 μm. The writing data is read from the storage device 140, and the pattern density ρ′ (pattern area density) of the pattern arranged in the proximity mesh region is calculated for each proximity mesh region.

Next, the proximity effect-corrected dose Dp for correcting the proximity effect is calculated for each proximity mesh region. A correction model of the proximity effect-corrected dose Dp and a calculation method thereof may be similar to the method used in the conventional single beam writing method.

The dose map generation unit 52 (another example of the dose information map acquisition unit) generates a dose map (another example of the dose information map) in which the calculated dose D (another example of the dose information) is defined for each pixel 36. Here, for example, a product of the proximity effect-corrected dose Dp and the pattern area density ρ excluding the base doses of the beam Dbase is calculated as the dose d (another example of the dose information), and a dose map (another example of the dose information map) in which the calculated dose d (another example of the dose information) is defined is preferably generated for each pixel 36. As a result, the dose d of each pixel 36 can be defined as, for example, a relative value normalized with the base doses of the beam Dbase as 1.

As the reference bias amount setting step (S110), the reference bias amount setting unit 54 sets a reference bias amount (reference correction amount) for correcting the dose information. In a case where the line width size of the pattern is increased as the reference bias amount, for example, a negative value is set. In a case where the line width size of the pattern is reduced, for example, a positive value is set. Here, for example, F=−0.1 is set.

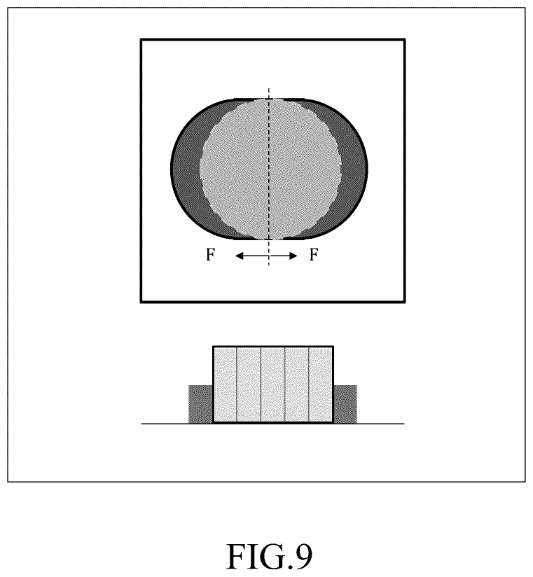

FIG. 9 is a diagram illustrating an example of a transformed advection model in the first embodiment. In the transformed advection model according to the first embodiment, an advection equation is transformed to define a transformed advection equation (1-1). Equation (1-1) can be transformed into Equation (1-2).

$$\frac{\partial ϕ}{\partial t} + F \vert ∇ ϕ \vert = 0 \qquad ( 1 - 1 )$$

$$\frac{\partial ϕ}{\partial t} + F \sqrt{{( {∇}_{x} ϕ )}^{2} + {( {∇}_{y} ϕ )}^{2}} = 0 \qquad ( 1 - 2 )$$

In Equation (1-1), as illustrated in FIG. 9, by providing an absolute value to the product of a function ∇ obtained using the gradient and a dose φ, a value obtained using the reference bias amount F and the gradient ∇ is added to the original dose φ on both sides of the pattern along the direction of the gradient. By performing the repetitive calculation a predetermined number of times, the pixels to which the value obtained from the reference bias amount F is added expand (or narrow) on both sides of the pattern each time. According to Equation (1-2), the pixels to which a value obtained using the bias amount F and the gradient-dependent function ∇ is added expand (or narrow) in the x direction and the y direction which are the directions of the gradients. In this way, since the correction amount biased by the gradient value changes, first, the gradient is calculated for each pixel.

As the gradient calculation step (S112), the gradient calculation unit 56 calculates, for each pixel 36, a gradient ∇ of the dose information defined for the pixel 36 using the dose information defined for the pixel 36 and the dose information defined for the pixel 36 around the pixel 36. The calculated gradient ∇ of the dose information is stored in the storage device 142, for example.

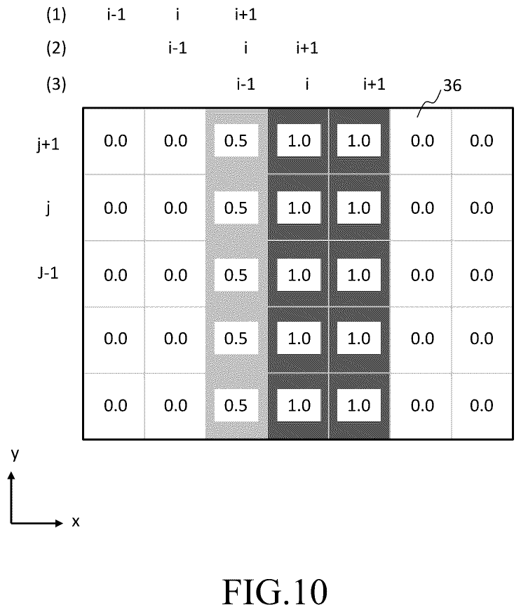

FIG. 10 is a diagram illustrating a part of an example of the dose information map in the first embodiment. FIG. 10 illustrates a dose map obtained by rasterizing a line pattern extending in the y direction, for example. In the example of FIG. 10, for example, the dose d of each pixel 36 normalized with the base doses of the beam Dbase as 1 is defined.

In the example of FIG. 10, 0 is defined for each pixel in the first column from the left and each pixel in the second column, 0.5 is defined for each pixel in the third column, 1.0 is defined for each pixel in the fourth column and each pixel in the fifth column, and 0 is defined for each pixel in the sixth column and each pixel in the seventh column. For such a dose map, the gradient calculation unit 56 calculates, for each pixel, a gradient of dose information φ using peripheral pixels (or “adjacent pixels”) that are adjacent in the x direction and the y direction. As the gradient of the dose information φ, a gradient of the dose information φ between the target pixel i, j and the peripheral pixel i+1, j one ahead in the x direction, a gradient of the dose information φ between the target pixel i, j and the peripheral pixel i−1, j one behind in the x direction, a gradient of the dose information φ between the target pixel i, j and the peripheral pixel i, j+1 one ahead in the y direction, and a gradient of the dose information φ between the target pixel i, j and the peripheral pixel i, j−1 one behind in the y direction are calculated.

In a case (1), for example, a pixel in the second column from the left and the second row from the top is defined as a pixel ij. In such a case (1), φᵢ−φᵢ₋₁=0 and φᵢ₊₁−φᵢ=0.5 are obtained in the x direction. In the y direction, φⱼ−φⱼ₋₁=0 and φⱼ₊₁−φⱼ=0 are obtained.

In a case (2), for example, a pixel in the third column from the left and the second row from the top is defined as a pixel ij. In such a case (2), φᵢ−φᵢ₋₁=0.5 and φᵢ₊₁−φᵢ=0.5 are obtained in the x direction. In the y direction, φⱼ−φⱼ₋₁=0 and φⱼ₊₁−φⱼ=0 are obtained.

In a case (3), for example, a pixel in the fourth column from the left and the second row from the top is defined as a pixel ij. In such a case (3), φᵢ−φᵢ₋₁=0.5 and φᵢ₊₁−φᵢ=0 are obtained in the x direction. In the y direction, φⱼ−φⱼ₋₁=0 and φⱼ₊₁−φⱼ=0 are obtained. Similarly, gradients of the other pixels are calculated.

As the individual bias correction amount calculation step (S114), the individual bias correction amount calculation unit 58 reads the gradient value from the storage device 142, for example, and calculates an individual correction amount of the dose information of the pixel 36 to be applied along the gradient direction for each pixel 36 using the calculated gradient value and the reference correction amount F. The above-described Equation (1-2) can be transformed into the following Equation (2-1). Further, the function ∇⁺ is defined by Equation (2-2). The function ∇⁻ is defined by Equation (2-3).

$${ϕ}_{i , j}^{n + 1} = {ϕ}_{i , j}^{n} - Δ t * ( max ( {F}_{i , j} , 0 ) {∇}^{+} + min ( {F}_{i , j} , 0 ) {∇}^{-} ) \qquad ( 2 - 1 )$$

$${∇}^{+} = {[ {max ( \frac{{ϕ}_{i}^{n} - {ϕ}_{i - 1}^{n}}{dx} , 0 )}^{2} + {min ( \frac{{ϕ}_{i + 1}^{n} - {ϕ}_{i}^{n}}{dx} , 0 )}^{2} + {max ( \frac{{ϕ}_{j}^{n} - {ϕ}_{j - 1}^{n}}{dy} , 0 )}^{2} + {min ( \frac{{ϕ}_{j + 1}^{n} - {ϕ}_{j}^{n}}{dy} , 0 )}^{2} ]}^{\frac{1}{2}} \qquad ( 2 - 2 )$$

$${∇}^{-} = {[ {min ( \frac{{ϕ}_{i}^{n} - {ϕ}_{i - 1}^{n}}{dx} , 0 )}^{2} + {max ( \frac{{ϕ}_{i + 1}^{n} - {ϕ}_{i}^{n}}{dx} , 0 )}^{2} + {min ( \frac{{ϕ}_{j}^{n} - {ϕ}_{j - 1}^{n}}{dy} , 0 )}^{2} + {max ( \frac{{ϕ}_{j + 1}^{n} - {ϕ}_{j}^{n}}{dy} , 0 )}^{2} ]}^{\frac{1}{2}} \qquad ( 2 - 3 )$$

In the example of FIG. 10, for example, in the case (1) in which the pixel in the second column from the left and the second row from the top is defined as the pixel ij, since φᵢ−φᵢ₋₁=0, φᵢ₊₁−φᵢ=0.5, φⱼ−φⱼ₋₁=0, and φⱼ₊₁−φⱼ=0 are obtained, ∇⁺ becomes 0. ∇⁻ is 0.5/dx. In a case of F=−0.1, the (n+1)-th dose information φn+1=φn−Δt (−0.1×0.5/dx) is obtained from Equation (2-1). In a case of Δt/dx=1, φn+1=φn+0.05 is obtained. Therefore, the bias correction to 0.05 is performed.

For example, in the case (2) in which the pixel in the third column from the left and the second row from the top is defined as a pixel ij, since φᵢ−φᵢ₋₁=0.5, φᵢ₊₁−φᵢ=0.5, φⱼ−φⱼ₋₁=0, and φⱼ₊₁−φⱼ=0 are obtained, ∇⁺ is 0.5/dx. ∇⁻ is 0.5/dx. In a case of F=−0.1, the (n+1)-th dose information φn+1=φn−Δt (−0.1×0.5/dx) is obtained from Equation (2-1). In a case of Δt/dx=1, φn+1=φn+0.05 is obtained. Therefore, the bias correction to 0.55 is performed.

For example, in the case (3) where the pixel in the fourth column from the left and the second row from the top is defined as a pixel ij, since φᵢ−φᵢ₋₁=0.5, φᵢ₊₁−φᵢ=0, φⱼ−φⱼ₋₁=0, and φⱼ₊₁−φⱼ=0 are obtained, ∇⁺ is 0.5/dx. ∇⁻ is 0. In a case of F=−0.1, the (n+1)-th dose information φn+1=φn−Δt (−0.1×0) is obtained from Equation (2-1). In a case of Δt/dx=1, φn+1=φn is obtained. Therefore, 1.0 remains.

Similarly, calculation processing on the other pixels is performed.

As the corrected dose map generation step (S120), the corrected dose map generation unit 60 generates, for each pixel 36, a corrected dose information map defining corrected dose information obtained by correcting the dose information of the pixel 36 using the calculated individual bias correction amount (individual correction amount).

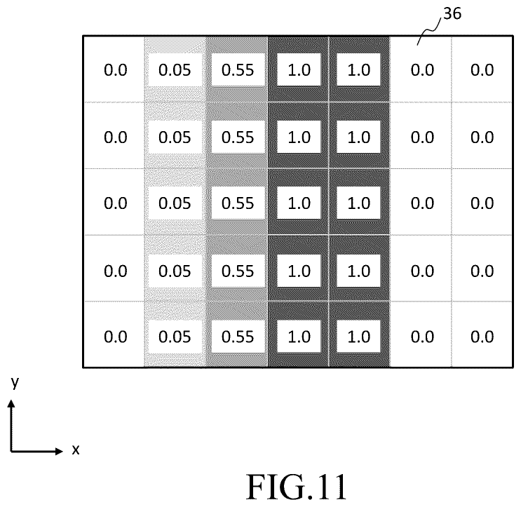

FIG. 11 is a diagram illustrating a part of an example of a corrected dose information map after first bias calculation processing in the first embodiment. FIG. 11 illustrates a result of performing bias calculation processing once for each pixel in FIG. 10.

For example, in the case (1) where the pixel in the second column from the left and the second row from the top is defined as a pixel ij, the bias correction is performed from 0 to 0.05.

For example, in the case (2) where the pixel in the third column from the left and the second row from the top is defined as a pixel ij, the bias correction is performed from 0.5 to 0.55.

For example, in the case (3) where the pixel in the fourth column from the left and the second row from the top is defined as a pixel ij, 1.0 remains even if the bias correction is performed from 1.0.

Similarly, the corrected dose information map illustrated in FIG. 11 is generated by defining the bias correction result for the other pixels. As illustrated in FIG. 11, for example, it can be seen that by the bias correction, the dose of each pixel in the second column from the left is changed from 0 to a finite value, and the correction can be made so that the line width of the pattern is widened. The generated corrected dose information map is output to and stored in the storage device 142, for example.

In the example described above, the dose map in which the dose d is defined as the dose information is illustrated as an example, and the corrected dose map obtained by performing the bias correction is illustrated as an example of the dose information map, but the dose information map is not limited thereto. As the dose information, for example, an area density map in which the area density ρ of the pattern is defined may be used. A correction area density map is preferably generated as an example of the dose information map by performing the bias correction on the area density map.

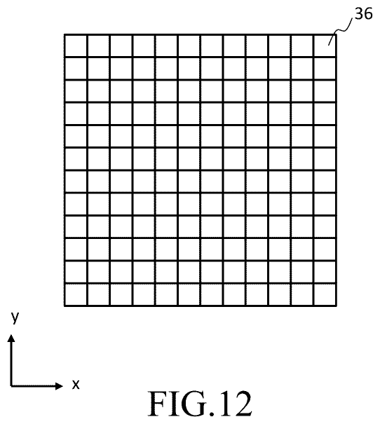

FIG. 12 is a diagram illustrating an example of a reference bias amount map in the first embodiment. In the above-described example, a unique value is used as the reference bias amount F, but the present invention is not limited thereto. As the reference bias amount F (reference correction amount), a reference bias amount map (reference correction amount map) in which the value of the reference bias amount F is individually defined for each pixel 36 is suitably used.

Alternatively, as the reference bias amount F (reference correction amount), a reference bias amount Fx (first reference correction amount) for the x direction (first direction) and a reference bias amount Fy (second reference correction amount) for the y direction (second direction) orthogonal to the x direction having a value different from the reference bias amount Fx are preferably set. In such a case, Equation (1-1) can be transformed into the following Equation (3-1). However, a matrix I defining the reference bias amount Fx and the reference bias amount Fy is expressed by Equation (3-2). In addition, a function non is expressed by Equation (3-3). Equation (3-1) can be transformed into Equation (3-4).

$$\frac{\partial ϕ}{\partial t} + Γ ( ∇ ϕ ) \cdot n = 0 \qquad ( 3 - 1 )$$

$$Γ = [ \begin{matrix}{F}_{x} & 0 \\ 0 & {F}_{y}\end{matrix} ] \qquad ( 3 - 2 )$$

$$n \cdot n = \frac{∇ ϕ}{\vert ∇ ϕ \vert} \cdot n = 1 \qquad ( 3 - 3 )$$

$$\frac{\partial ϕ}{\partial t} + \frac{{F}_{x} {\vert {∇}_{x} ϕ \vert}^{2} + {F}_{y} {\vert {∇}_{y} ϕ \vert}^{2}}{\sqrt{{\vert {∇}_{x} ϕ \vert}^{2} + {\vert {∇}_{y} ϕ \vert}^{2}}} = 0 \qquad ( 3 - 4 )$$

Equation (3-4) can be transformed into the following Equation (4-1). Furthermore, the function ∇⁺ is defined by Equation (4-2). The function ∇⁻ is defined by Equation (4-3).

$${ϕ}_{i , j}^{n + 1} = {ϕ}_{i , j}^{n} - Δ t * [ \frac{1}{{∇}^{+}} ( max ( {Fx}_{i , j} , 0 ) {∇}_{x}^{+ 2} + max ( {Fy}_{i , j} , 0 ) {∇}_{y}^{+ 2} ) + \frac{1}{{∇}^{-}} ( min ( {Fx}_{i , j} , 0 ) {∇}_{x}^{- 2} + min ( {Fy}_{i , j} , 0 ) {∇}_{y}^{- 2} ) ] \qquad ( 4 - 1 )$$

$${∇}^{+} = {[ {max ( \frac{{ϕ}_{i}^{n} - {ϕ}_{i - 1}^{n}}{dx} , 0 )}^{2} + {min ( \frac{{ϕ}_{i + 1}^{n} - {ϕ}_{i}^{n}}{dx} , 0 )}^{2} + {max ( \frac{{ϕ}_{j}^{n} - {ϕ}_{j - 1}^{n}}{dy} , 0 )}^{2} + {min ( \frac{{ϕ}_{j + 1}^{n} - {ϕ}_{j}^{n}}{dy} , 0 )}^{2} ]}^{\frac{1}{2}} \qquad ( 4 - 2 )$$

$${∇}^{-} = {[ {min ( \frac{{ϕ}_{i}^{n} - {ϕ}_{i - 1}^{n}}{dx} , 0 )}^{2} + {max ( \frac{{ϕ}_{i + 1}^{n} - {ϕ}_{i}^{n}}{dx} , 0 )}^{2} + {min ( \frac{{ϕ}_{j}^{n} - {ϕ}_{j - 1}^{n}}{dy} , 0 )}^{2} + {max ( \frac{{ϕ}_{j + 1}^{n} - {ϕ}_{j}^{n}}{dy} , 0 )}^{2} ]}^{\frac{1}{2}} \qquad ( 4 - 3 )$$

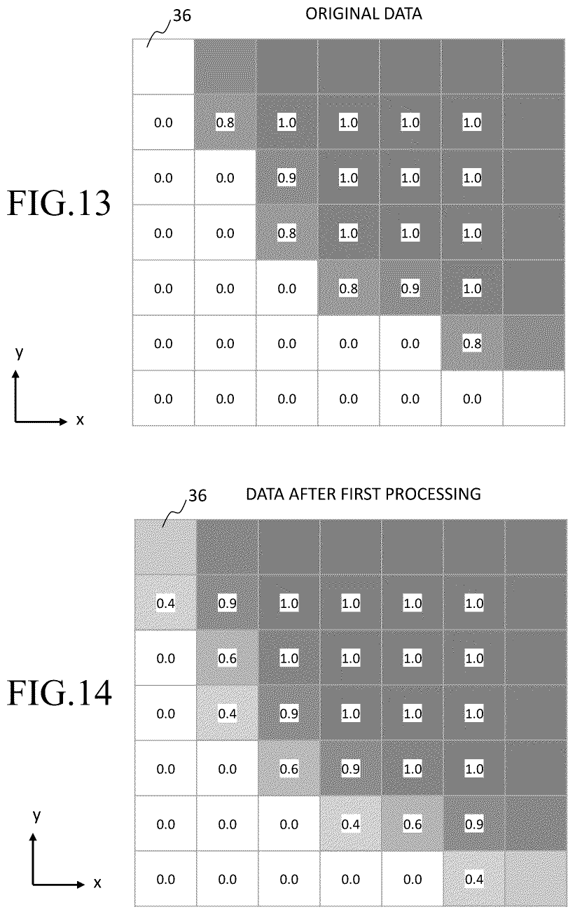

FIG. 13 is a diagram illustrating a part of an example of an original dose information map before bias calculation processing in the first embodiment. In the example of FIG. 13, an example of a dose information map of an arc portion of a certain pattern is illustrated.

FIG. 14 is a diagram illustrating a part of an example of a corrected dose information map after first bias calculation processing in the first embodiment. In the example of FIG. 14, an example of a result after the first bias calculation processing in which different reference bias amounts Fx and Fy are applied in the x and y directions to the original dose information map of FIG. 13 is illustrated.

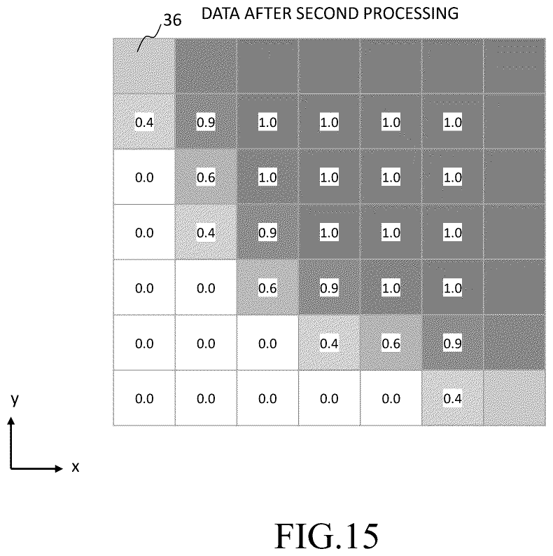

FIG. 15 is a diagram illustrating a part of an example of a corrected dose information map after second bias calculation processing in the first embodiment. In the example of FIG. 15, an example of a result after the second bias calculation processing in which the reference bias amounts Fx and Fy are applied to the corrected dose information map of FIG. 14 is illustrated. As illustrated in FIGS. 14 and 15, in the bias calculation processing in the first embodiment, the gradient calculation processing for each pixel 36 and the individual correction amount calculation processing for each pixel 36 are preferably performed repeatedly up to a preset number of times. The number of times of the calculation processing is set in advance. In the examples of FIGS. 13 to 15, a case where calculation processing is performed twice is illustrated. In the examples of FIGS. 10 and 11, a case where the calculation processing is performed once is illustrated. Alternatively, the gradient calculation processing and the individual correction amount calculation processing for each pixel 36 are preferably performed repeatedly until the corrected dose information has accuracy set in advance.

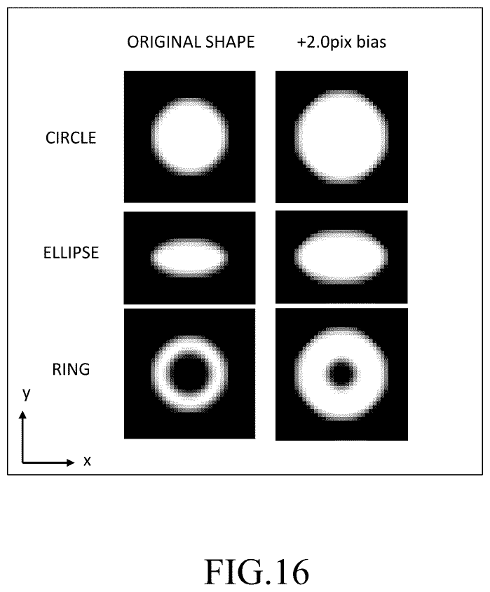

FIG. 16 is a diagram illustrating an example of a map image corresponding to a dose information map after bias correction in the first embodiment. In the example of FIG. 16, a result of performing the bias correction calculation processing twice for each pixel with respect to a circular pattern, a result of performing the bias correction calculation processing twice for each pixel with respect to an elliptic pattern, and a result of performing the bias correction calculation processing twice for each pixel with respect to a ring pattern are illustrated. In either case, it can be seen that the pattern size (outer peripheral diameter size) to be written increases by the bias correction with respect to the dose information map. In addition, it can be seen that the inner peripheral diameter size of the ring decreases (the pattern becomes thick).

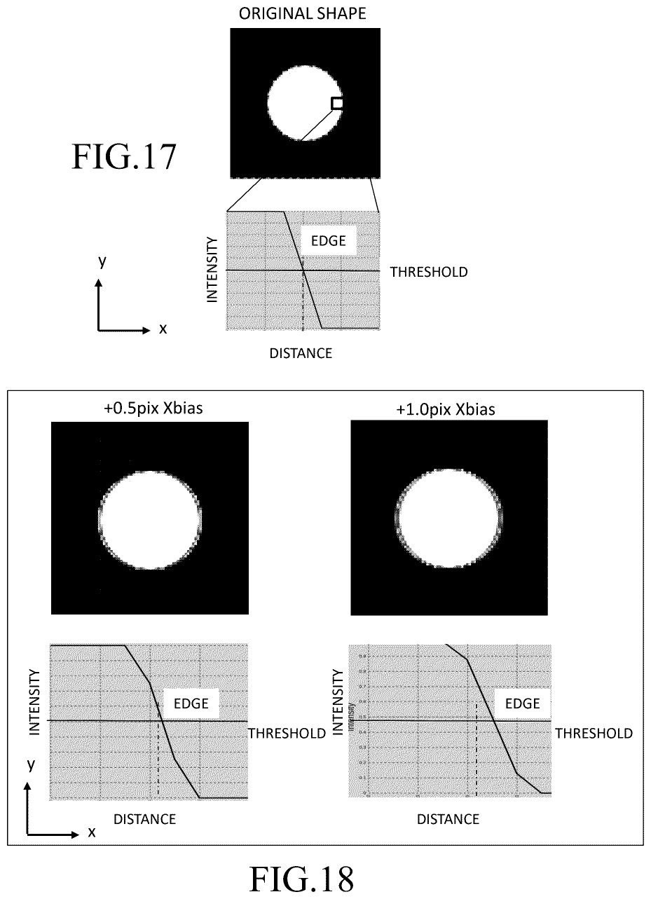

FIG. 17 is a diagram illustrating an example of a map image and a dose corresponding to a dose information map before bias correction in the first embodiment.

FIG. 18 is a diagram illustrating an example of a map image and a dose corresponding to a corrected dose information map after bias correction in the first embodiment. As illustrated in FIG. 18, it can be seen that, in a position of a pattern edge resolved by a resist, the position of the edge on the right side of the pattern in the case of performing the first bias correction in units of 0.5 pixels in the x direction moves in the x direction as compared with the position before the correction. In addition, it can be seen that the position of the pattern edge in the case of performing the second bias correction further moves in the x direction as compared with the first correction result.

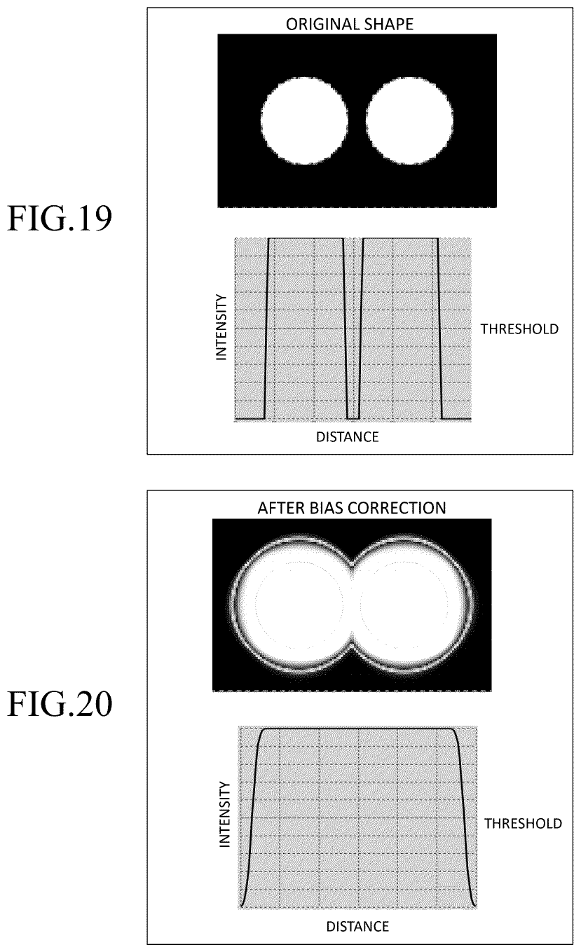

FIG. 19 is a diagram illustrating an example of a map image and a dose corresponding to a dose information map of two adjacent circle patterns before bias correction in the first embodiment.

FIG. 20 is a diagram illustrating an example of a map image and a dose corresponding to a dose information map of two adjacent circle patterns after bias correction in the first embodiment.

As illustrated in FIG. 19, as a result of performing the bias correction in the first embodiment on the two circle patterns initially arranged apart from each other, it can be seen that the dose information map of the pattern integrated as illustrated in FIG. 20 can be obtained without performing the logical operation on the edge overlapping portion.

As the writing step (S130), first, the shot data generation unit 70 calculates the beam irradiation time for each pixel 36 from the corrected dose information defined in the corrected dose information map. When the dose information defined in the corrected dose information map is the dose d, the dose d is multiplied by the base doses of the beam Dbase, and then divided by the current density J, whereby the beam irradiation time t can be calculated. When the dose information defined in the corrected dose information map is the area density ρ, the shot data generation unit 70 uses the area density ρ defined in the corrected dose information map to calculate the dose d for each pixel 36 by a method similar to the method described above. Then, the dose d is multiplied by the base doses of the beam Dbase, and then divided by the current density J, whereby the beam irradiation time t can be calculated.

Then, the shot data generation unit 70 generates a beam irradiation time map in which beam irradiation time data (shot data) for each pixel 36 is defined. Next, the shot data generation unit 70 rearranges the beam irradiation time data in shot order and outputs the data to the storage device 142.

Under the control of the writing control unit 72, the writing mechanism 150 writes a pattern on the target object 101 with the multiple beams 20 of the dose based on the corrected dose information defined in the generated corrected dose information map.

As described above, according to the first embodiment, the bias correction can be performed on the pixel data of the information such as the dose of the multiple beams 20 without considering the position of the pattern edge. Furthermore, even in a case where edges of adjacent patterns overlap each other on data by bias correction, the logical operation processing of the overlapping region can be made unnecessary. As a result, when a mask pattern is exposed and transferred to a substrate such as a wafer using a mask subjected to processing such as etching on the written target object 101, a pattern of a desired size can be transferred to the substrate.

### Second Embodiment

In a second embodiment, a configuration for processing dose information in an edge peripheral region of a pattern using bias correction will be described. In the second embodiment, points not specifically described below are similar to those in the first embodiment.

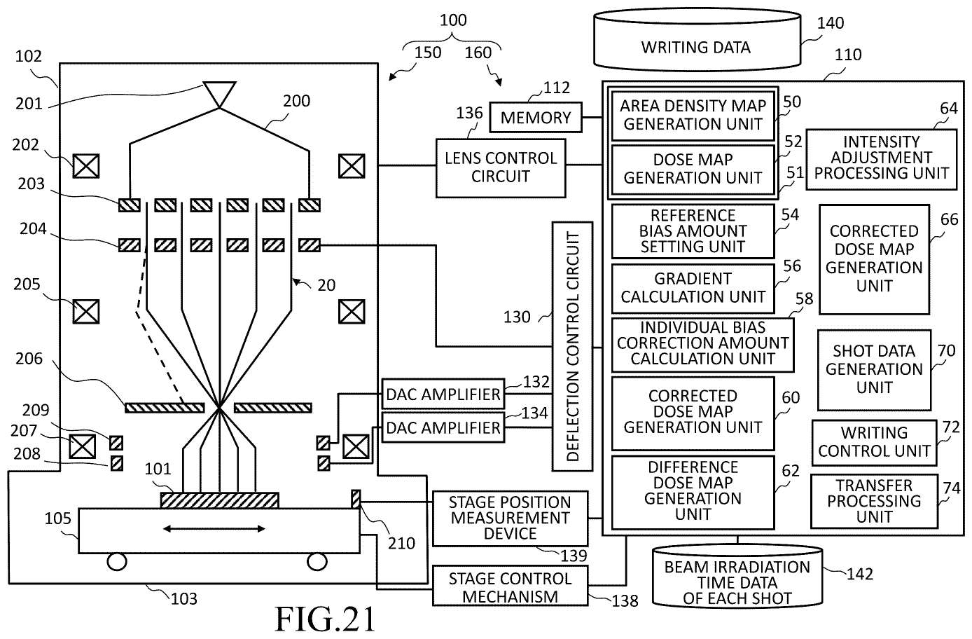

FIG. 21 is a conceptual diagram illustrating an example of a configuration of a writing apparatus in the second embodiment. FIG. 21 is similar to FIG. 1 except that a difference dose map generation unit 62, an intensity adjustment processing unit 64, and a corrected dose map generation unit 66 are added to a control computer 110.

Each “unit” such as a rasterization processing unit 51 (an area density map generation unit 50 and a dose map generation unit 52), a reference bias amount setting unit 54, a gradient calculation unit 56, an individual bias correction amount calculation unit 58, a corrected dose map generation unit 60, the difference dose map generation unit 62, the intensity adjustment processing unit 64, the corrected dose map generation unit 66, a shot data generation unit 70, a writing control unit 72, and a transfer processing unit 74 includes a processing circuit. The processing circuit includes an electric circuit, a computer, a processor, a circuit board, a quantum circuit, or a semiconductor device, for example. Each “unit” may use a common processing circuit (the same processing circuit) or may use a different processing circuit (a separate processing circuit). Information input to and output from the rasterization processing unit 51 (the area density map generation unit 50 and the dose map generation unit 52), the reference bias amount setting unit 54, the gradient calculation unit 56, the individual bias correction amount calculation unit 58, the corrected dose map generation unit 60, the difference dose map generation unit 62, the intensity adjustment processing unit 64, the corrected dose map generation unit 66, the shot data generation unit 70, the writing control unit 72, and the transfer processing unit 74 and information during calculation are stored in the memory 112 each time.

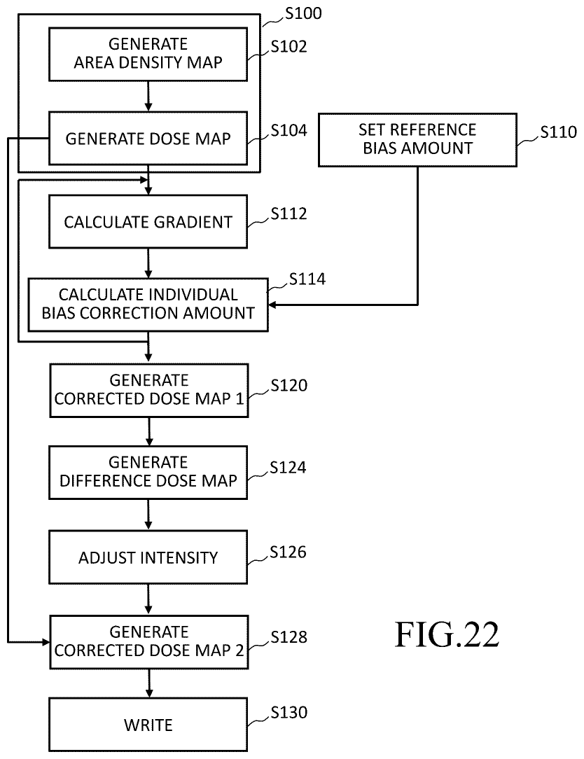

FIG. 22 is a flowchart illustrating an example of main steps of a writing method in the second embodiment. In FIG. 22, a corrected dose map generation step (S120) in FIG. 8 is referred to as a corrected dose map 1 generation step (S120). FIG. 22 is similar to FIG. 8 except that a difference dose map generation step (S124), an intensity adjustment step (S126), and a corrected dose map 2 generation step (S128) are added between the corrected dose map 1 generation step (S120) and a writing step (S130).

In a dose information acquisition method for an edge peripheral region of a figure pattern in the second embodiment, each step from the rasterization processing step (S100) to the difference dose map generation step (S124) is performed. In a dose information correction method for the edge peripheral region of the figure pattern in the second embodiment, each step from the rasterization processing step (S100) to the corrected dose map 2 generation step (S128) is performed.

The contents of the rasterization processing step (S100), the reference bias amount setting step (S110), the gradient calculation step (S112), the individual bias correction amount calculation step (S114), and the corrected dose map 1 generation step (S120) are similar to those in the first embodiment.

As the difference dose map generation step (S124), the difference dose map generation unit 62 calculates a difference between the dose information map (for example, the dose map) generated in the rasterization processing step (S100) and the corrected dose information map 1 (for example, the corrected dose map 1) generated in the corrected dose map 1 generation step (S120), thereby generating an edge peripheral region dose information map (for example, an edge peripheral dose map or a difference dose map) in which dose information of the edge peripheral region of the figure pattern is defined for each pixel 36. The generated edge peripheral region dose information map is output and stored in, for example, the storage device 142.

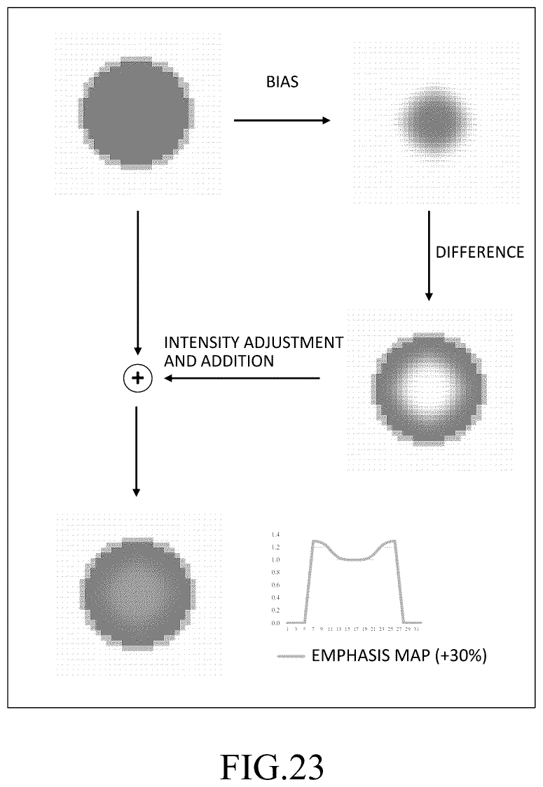

FIG. 23 is a diagram illustrating an example of an image from generation of a dose information map to generation of a corrected dose map using an edge peripheral region dose information map in the second embodiment. In the corrected dose information map 1 (for example, the corrected dose map 1), as described above, dose information for thickening or thinning the line width of the pattern is defined. Therefore, by taking a difference between the dose information map (for example, the dose map) and the corrected dose information map 1 (for example, the corrected dose map 1), it is possible to generate the edge peripheral region dose information map (for example, the edge peripheral dose map) for emphasizing the edge peripheral region of the dose information map. When the difference is taken, the thinner one of the dose information map and the corrected dose information map 1 is subtracted from the thicker one.

For example, when the corrected dose information map 1 is generated by bias correction for thinning the line width of the pattern, the corrected dose information map 1 (for example, the corrected dose map 1) is subtracted from the dose information map (for example, the dose map). As a result, map data for mainly emphasizing the pixels in the edge peripheral region on the inner side from the edge position including the pixels where the edge is located in the dose information map can be acquired as the edge peripheral region dose information map. In the example of FIG. 23, a case where the corrected dose information map is generated by bias correction for thinning the line width of the pattern is illustrated as an example.

Conversely, when the corrected dose information map 1 is generated by bias correction for thickening the line width of the pattern, the dose information map (for example, the dose map) is subtracted from the corrected dose information map 1 (for example, the corrected dose map 1) having a larger figure. As a result, map data for mainly emphasizing pixels in the outer edge peripheral region from the edge position can be acquired as the edge peripheral region dose information map.

As the intensity adjustment step (S126), the intensity adjustment processing unit 64 performs conversion processing on the edge peripheral region dose information map by an arbitrary function to adjust the intensity of the edge peripheral region dose information map. For example, the dose information map is converted by multiplying the dose information of each pixel 36 in the edge peripheral region dose information map by a proportionality coefficient using a proportional function. The dose information of each pixel 36 is converted into, for example, 30% intensity. The dose information of the pixels other than the edge peripheral region is a smaller value or zero due to the difference. Therefore, a map in which how much pixels in the edge peripheral region are emphasized is adjusted can be obtained.

Note that, in a case where it is desired to extract only the edge peripheral portion by setting the small value to zero, filtering may be performed with a threshold sufficiently smaller than the resolution of the grayscale.

As the corrected dose map 2 generation step (S128), the corrected dose map generation unit 66 generates an edge peripheral corrected dose information map around the edge in which the dose information of the edge peripheral region of the figure pattern is corrected by adding the edge peripheral region dose information map in which how much emphasis is performed is adjusted to the dose information map (for example, the dose map). In other words, the corrected dose map generation unit 66 adds the edge peripheral region dose information map in which the intensity is adjusted in the intensity adjustment step (S126) to the dose information map (for example, the dose map) generated in the rasterization processing step (S100). As a result, the corrected dose information map 2 (for example, the corrected dose map 2) in which the edge peripheral region is corrected with a desired intensity is generated.

Note that the intensity adjustment processing unit 64 can also convert the intensity into a negative intensity in the intensity adjustment step (S126), and in a case where the intensity is converted into a negative intensity, the edge can be corrected in a direction opposite to emphasis, that is, in a direction in which emphasis is not performed.

The intensity adjustment step (S126) may be omitted, and the corrected dose map generation unit 66 may add the edge peripheral region dose information map generated in the difference dose map generation step (S124) to the dose information map (for example, the dose map) generated in the rasterization processing step (S100). When the corrected dose information map 1 is generated by the bias correction for thinning the line width of the pattern in the corrected dose map 1 generation step (S120), the dose information of the pixels other than the edge peripheral region is a small value or 0 due to the difference, and thus the corrected dose information map 2 (for example, the corrected dose map 2) in which the edge peripheral region of the dose information map is corrected to about twice is generated by the corrected dose map generation step (S128). The generated corrected dose information map 2 (for example, the corrected dose map 2) is output and stored in, for example, the storage device 142.

The point where the edge peripheral region is emphasized can also be seen from the fact that the dose profile of the corrected dose information map 2 (for example, the corrected dose map 2) after addition in which the edge portion is enlarged is shown in the example of FIG. 23.

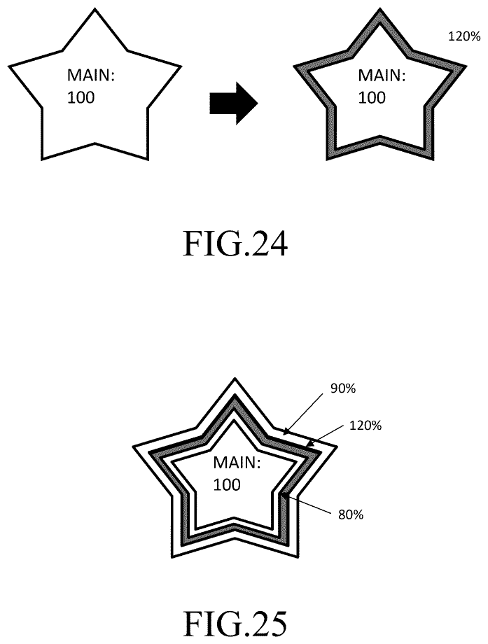

FIG. 24 is a diagram illustrating an example of a pattern in which an edge is emphasized in the second embodiment. The example of FIG. 24 shows that when a main pattern has a dose of 100% and the intensity adjustment is 20% by edge correction when the corrected dose information map 1 illustrated in the second embodiment is generated by bias correction for thinning the line width of the pattern, the edge peripheral region (edge peripheral region on the inner side from the edge position including the pixel where the edge is located) of the main pattern can have a dose of 120%.

FIG. 25 is a diagram illustrating another example of a pattern in which an edge is emphasized in the second embodiment. In the example of FIG. 25, by repeating the edge correction including the bias correction and illustrated in the second embodiment, the edge peripheral region of the main pattern can be divided into a plurality of regions, and each region can be adjusted to an arbitrary intensity. The example of FIG. 25 shows that when the main pattern has a dose of 100%, the first-stage edge peripheral region of the main pattern can have a dose of 808, the second-stage edge peripheral region outside the first-stage edge peripheral region can have a dose of 1208, and the third-stage edge peripheral region outside the second-stage edge peripheral region can have a dose of 90%.

In the example described above, the case where the intensity of the edge peripheral region dose information map after the difference is adjusted has been described, but the present invention is not limited thereto.

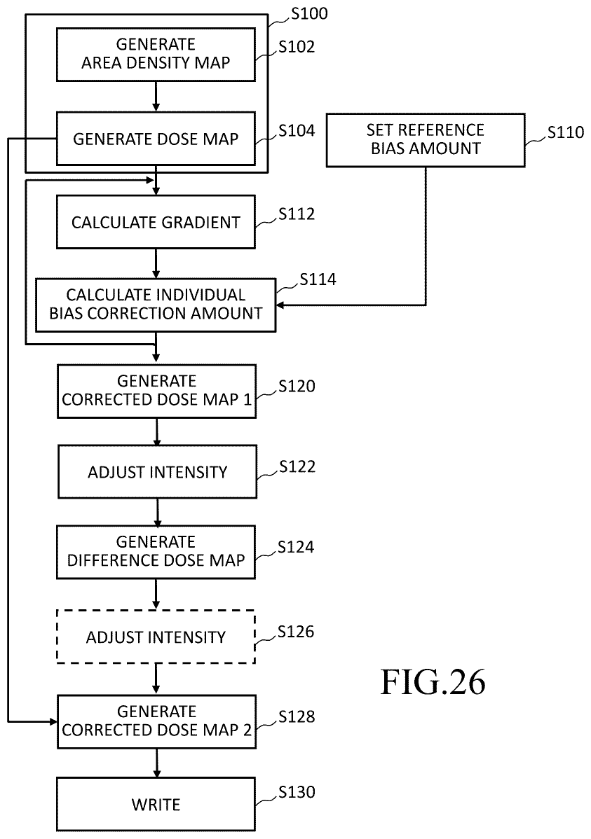

FIG. 26 is a flowchart illustrating an example of main steps of a writing method in a first modification of the second embodiment. FIG. 26 is similar to FIG. 22 except that the intensity adjustment step (S122) is added between the corrected dose map 1 generation step (S120) and the difference dose map generation step (S124) instead of or in addition to the intensity adjustment step (S126).

The contents of the rasterization processing step (S100), the reference bias amount setting step (S110), the gradient calculation step (S112), the individual bias correction amount calculation step (S114), and the corrected dose map 1 generation step (S120) are similar to those in the first embodiment.

As the intensity adjustment step (S122) in the first modification of the second embodiment, before generating the edge peripheral region dose information map (for example, the difference dose map), the intensity adjustment processing unit 64 performs conversion processing on the corrected dose information map 1 (for example, the corrected dose map 1) generated in the corrected dose map generation step (S120) by an arbitrary function, and adjusts the intensity of the dose information of each pixel of the corrected dose information map 1 (for example, the corrected dose map 1). For example, the dose information map is converted by multiplying the dose information of each pixel 36 in the corrected dose information map 1 (for example, the corrected dose map 1) by a proportionality coefficient using a proportional function. The dose information of each pixel 36 is converted into, for example, 70% intensity.

As the difference dose map generation step (S124) in the first modification of the second embodiment, the difference dose map generation unit 62 takes a difference between the dose information map generated in the rasterization processing step (S100) and the corrected dose information map 1 in which the intensity is adjusted in the intensity adjustment step (S122), thereby generating an edge peripheral region dose information map (for example, an edge peripheral dose map or a difference dose map) in which dose information of an edge peripheral region of a figure pattern is defined for each pixel 36. The generated edge peripheral region dose information map is output and stored in, for example, the storage device 142.

Then, the process proceeds to the corrected dose map generation step (S128) without adjusting the intensity of the edge peripheral region dose information map. Alternatively, the intensity adjustment of the edge peripheral region dose information map may be performed in the intensity adjustment step (S126).

A corrected dose information map 2 is obtained by adding the difference obtained in S124 to the dose information map (dose 100%) in $128. As the corrected dose information map 2, a map is obtained in which the dose around the inner edge of the original dose information map (mainly, the pixels in the edge peripheral region on the inner side from the edge position including the pixel where the edge is located are emphasized) is 200%, and the dose in the region (main portion) on the further inner side around the inner edge is 130%.

By inserting the intensity adjustment step (S122) in this manner, both the edge peripheral portion and the main region can be adjusted at the same time.

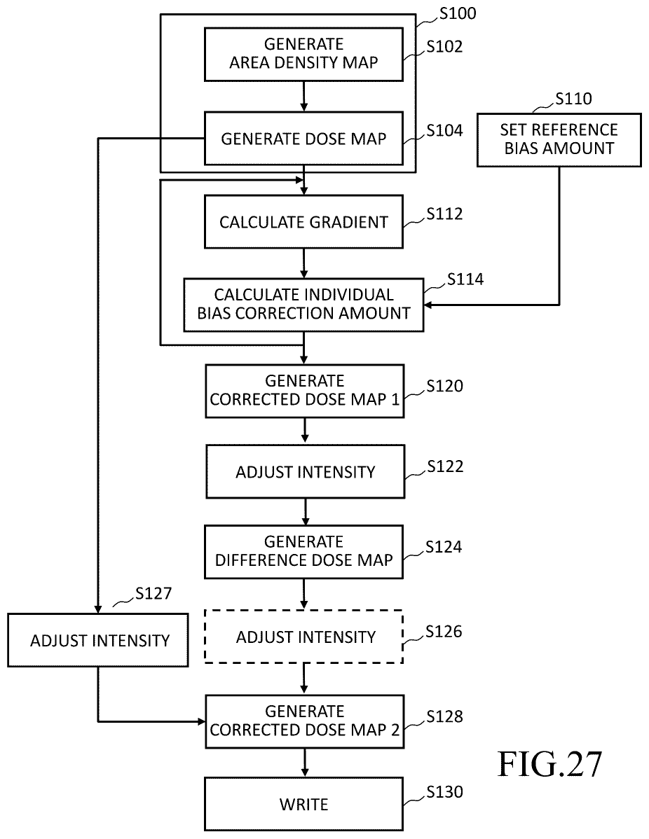

FIG. 27 is a flowchart illustrating an example of main steps of a writing method in a second modification of the second embodiment. FIG. 27 is similar to FIG. 26 except that an intensity adjustment step (S127) for adjusting the intensity is added between the dose map generation step (S104) and the corrected dose map 2 generation step (S128). In the first modification of the second embodiment, in FIG. 26, the dose information map generated in the dose map generation step (S104) is input to the corrected dose map 2 generation step (S128) as it is. In the second modification of the second embodiment, in the intensity adjustment step (S127), the intensity of the dose information map generated in the dose map generation step (S104) is adjusted and input to the corrected dose map 2 generation step (S128).

For example, in a case where the intensity adjustment of 70% is performed in the intensity adjustment step (S127) and the intensity adjustment is not performed in the intensity adjustment steps S122 and S126, in the corrected dose map 2 generation step (S128), a map is obtained in which the dose around the inner edge of the dose information map (mainly, the pixels in the edge peripheral region on the inner side from the edge position including the pixel where the edge is located are emphasized) is 170%, and the dose in the region (main portion) on the further inner side around the inner edge is 708. As described above, in the second modification of the second embodiment, it is possible to obtain a map in which the dose of the main portion is reduced to less than 100%.

The contents of the corrected dose map 2 generation step (S128) are similar to the contents described above.

As described above, the intensity may be adjusted after taking the difference, the intensity may be adjusted before taking the difference, or the intensity may be adjusted before and after taking the difference. Alternatively, the intensity may not be adjusted before and after the difference.

As the writing step (S130), the shot data generation unit 70 calculates the beam irradiation time for each pixel 36 from the corrected dose information defined in the corrected dose information map 2. When the dose information defined in the corrected dose information map 2 is the dose d, the dose d is multiplied by the base doses of the beam Dbase, and then divided by the current density J, whereby the beam irradiation time t can be calculated. When the dose information defined in the corrected dose information map 2 is the area density ρ, the shot data generation unit 70 uses the area density ρ defined in the corrected dose information map 2 to calculate the dose d for each pixel 36 by a method similar to the method described above. Then, the dose d is multiplied by the base doses of the beam Dbase, and then divided by the current density J, whereby the beam irradiation time t can be calculated.

Then, the shot data generation unit 70 generates a beam irradiation time map in which beam irradiation time data (shot data) for each pixel 36 is defined. Next, the shot data generation unit 70 rearranges the beam irradiation time data in shot order and outputs the data to the storage device 142.

Under the control of the writing control unit 72, the writing mechanism 150 writes a pattern on the target object 101 with the multiple beams 20 of the dose based on the dose information corrected using the edge peripheral region dose information map. Specifically, the writing mechanism 150 writes a pattern on the target object 101 with the multiple beams 20 of the dose based on the corrected dose information defined in the generated corrected dose information map 2.

As described above, according to the second embodiment, the dose information of the pixels in the edge peripheral region can be adjusted using the bias correction method.

The embodiments have been described with reference to the specific examples. However, the present invention is not limited to these specific examples. In the example described above, the configuration in which the edge peripheral region dose information map (for example, the difference dose map) is added to the dose information map (for example, the dose map) to generate the corrected dose information map 2 (for example, the corrected dose map 2) has been described, but the present invention is not limited thereto. For example, it is also preferable to generate the corrected dose information map 2 (for example, the corrected dose map 2) by adding the edge peripheral region dose information map (for example, the difference dose map) to the corrected dose information map 1 (for example, the corrected dose map 1).

In addition, the functions of the processing described in the above embodiments may be executed by a computer. A program for causing the computer to execute the functions of the processing may be stored in, for example, a non-transitory tangible computer-readable storage medium such as a magnetic disk device.

Further, descriptions of parts and the like that are not directly necessary for explanation of the present invention, such as an apparatus configuration and a control method, have been omitted. However, the necessary apparatus configuration and control method can be appropriately selected and used. For example, although the description of the control unit configuration for controlling the writing apparatus 100 is omitted, it goes without saying that the necessary control unit configuration is appropriately selected and used.

In addition, all dose information correction methods, dose information acquisition methods for an edge peripheral region of a figure pattern, charged particle beam writing apparatuses, and programs (or storage media), which include the elements of the present invention and can be appropriately changed in design by those skilled in the art, are included in the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A dose information correction method comprising:
acquiring a dose information map in which dose information related to a dose of a charged particle beam for writing a figure pattern on a target object with the charged particle beam is defined for each mesh region of a plurality of mesh regions obtained by dividing a writing region of the target object;
setting a reference correction amount for correcting the dose information;
calculating, for each mesh region, a gradient of the dose information defined for a mesh region by using the dose information defined for the mesh region and the dose information defined for a peripheral mesh region around the mesh region;
calculating, for each mesh region, an individual correction amount of the dose information of the mesh region to be applied along a direction of the gradient by using a value of a calculated gradient and the reference correction amount; and
generating and outputting a corrected dose information map in which corrected dose information obtained by correcting the dose information of the mesh region using a calculated individual correction amount is defined for each mesh region.

2. The method according to claim 1, wherein processing of calculating the gradient for each mesh region and processing of calculating the individual correction amount for the each mesh region are repeatedly performed up to a preset number of times.

3. The method according to claim 1, wherein a reference correction amount map in which a value of the reference correction amount is individually defined for each mesh region is used for obtaining the reference correction amount.

4. The method according to claim 1, wherein a first reference correction amount for a first direction and a second reference correction amount for a second direction orthogonal to the first direction having a value different from the first reference correction amount are set as the reference correction amount.

5. The method according to claim 1, wherein processing of calculating the gradient for each mesh region and processing of calculating the individual correction amount for each mesh region are repeatedly performed until the corrected dose information has accuracy set in advance.

6. A dose information acquisition method for an edge peripheral region of a figure pattern, the dose information acquisition method comprising:
acquiring a dose information map in which dose information related to a dose of a charged particle beam for writing a figure pattern on a target object with the charged particle beam is defined for each mesh region of a plurality of mesh regions obtained by dividing a writing region of the target object;
setting a reference correction amount for correcting the dose information;
calculating, for each mesh region, a gradient of the dose information defined for a mesh region by using the dose information defined for the mesh region and the dose information defined for a peripheral mesh region around the mesh region;
calculating, for each mesh region, an individual correction amount of the dose information of the mesh region to be applied along a direction of the gradient by using a value of a calculated gradient and the reference correction amount;
generating a corrected dose information map in which corrected dose information obtained by correcting the dose information of the mesh region using a calculated individual correction amount is defined for each mesh region; and
generating and outputting an edge peripheral region dose information map in which dose information of an edge peripheral region of a figure pattern is defined for each mesh region by calculating a difference between the dose information map and the corrected dose information map.

7. The method according to claim 6, further comprising:
converting the corrected dose information map by an arbitrary function before generating the edge peripheral region dose information map.

8. A dose information correction method comprising:
generating a dose information map in which dose information related to a dose of a charged particle beam for writing a figure pattern on a target object with the charged particle beam is defined for each mesh region of a plurality of mesh regions obtained by dividing a writing region of the target object;
acquiring an edge peripheral region dose information map by the method according to claim 6; and
generating and outputting an edge peripheral corrected dose information map in which dose information of the edge peripheral region of the figure pattern is corrected by adding an acquired edge peripheral region dose information map to the dose information map.

9. A charged particle beam writing apparatus comprising:
a dose information map acquisition circuit configured to acquire a dose information map in which dose information related to a dose of the charged particle beam for writing a figure pattern on a target object with the charged particle beam is defined for each mesh region of a plurality of mesh regions obtained by dividing a writing region of the target object;
a setting circuit configured to set a reference correction amount for correcting the dose information;
a gradient calculation circuit configured to calculate, for each mesh region, a gradient of the dose information defined for a mesh region by using the dose information defined for the mesh region and the dose information defined for a peripheral mesh region around the mesh region;
an individual correction amount calculation circuit configured to calculate, for each mesh region, an individual correction amount of the dose information of the mesh region to be applied along a direction of the gradient using a value of a calculated gradient and the reference correction amount;
a corrected dose information map generation circuit configured to generate a corrected dose information map in which corrected dose information obtained by correcting the dose information of the mesh region using a calculated individual correction amount is defined for each mesh region; and
a writing mechanism configured to write a pattern on the target object with a charged particle beam of a dose based on the corrected dose information defined in a generated corrected dose information map.

10. A charged particle beam writing apparatus comprising:
a dose information map acquisition circuit configured to acquire a dose information map in which dose information related to a dose of the charged particle beam for writing a figure pattern on a target object with the charged particle beam is defined for each mesh region of a plurality of mesh regions obtained by dividing a writing region of the target object;
a setting circuit configured to set a reference correction amount for correcting the dose information;
a gradient calculation circuit configured to calculate, for each mesh region, a gradient of the dose information defined for a mesh region by using the dose information defined for the mesh region and the dose information defined for a peripheral mesh region around the mesh region;
an individual correction amount calculation circuit configured to calculate, for each mesh region, an individual correction amount of the dose information of the mesh region to be applied along a direction of the gradient using a value of a calculated gradient and the reference correction amount;
a corrected dose information map generation circuit configured to generate a corrected dose information map in which corrected dose information obtained by correcting the dose information of the mesh region using a calculated individual correction amount is defined for each mesh region;
an edge peripheral region dose information map generating circuit configured to generate an edge peripheral region dose information map in which dose information of an edge peripheral region of a figure pattern is defined for each mesh region by calculating a difference between the dose information map and the corrected dose information map; and
a writing mechanism configured to write a pattern on the target object with a charged particle beam of a dose based on dose information corrected using the edge peripheral region dose information map.

11. A non-transitory computer-readable storage medium storing a program for causing a computer to execute processing comprising:
acquiring a dose information map in which dose information related to a dose of a charged particle beam for writing a figure pattern on a target object with the charged particle beam is defined for each mesh region of a plurality of mesh regions obtained by dividing a writing region of the target object;
setting a reference correction amount for correcting the dose information;
calculating, for each mesh region, a gradient of the dose information defined for a mesh region by using the dose information defined for the mesh region and the dose information defined for a peripheral mesh region around the mesh region;
storing a calculated gradient of the dose information in a storage device;
reading the gradient of the dose information from the storage device and calculating, for each mesh region, an individual correction amount of the dose information of the mesh region to be applied along a direction of the gradient using a value of a calculated gradient and the reference correction amount; and
generating and outputting a corrected dose information map in which corrected dose information obtained by correcting the dose information of the mesh region using a calculated individual correction amount is defined for each mesh region.
